(19) United States
(12) Patent Application Publication
(10) Pub. No.: US 2013/0256016 A1
(43) Pub. Date: Oct. 3, 2013

(54) PRINTED CIRCUIT BOARD AND MANUFACTURING METHOD THEREOF

(71) Applicant: FUJITSU LIMITED, Kawasaki-shi (JP)

(72) Inventor: Masakazu TAKESUE, Kawasaki (JP)

(21) Appl. No.: 13/726,106

(22) Filed: Dec. 22, 2012

(30) Foreign Application Priority Data
Mar. 30, 2012 (JP) 2012-079974

(51) Int. Cl. H05K 3/30; H05K 1/18

(52) U.S. Cl. CPC H05K 3/30; H05K 1/181
USPC 174/258; 29/832

(57) ABSTRACT

An embodiment of a printed circuit board includes: a mounting board with a solder resist on a front surface thereof; a component mounted on the mounting board; an underfill material that fixes the component to the mounting board; and resin materials dotted between the solder resist and the underfill material.

### CROSS-REFERENCE TO RELATED APPLICATION

This application is based upon and claims the benefit of priority of the prior Japanese Patent Application No. 2012-079974, filed on Mar. 30, 2012, the entire contents of which are incorporated herein by reference.

### FIELD

The embodiments discussed herein are directed to a printed circuit board and a manufacturing method of the same.

### BACKGROUND

In recent years, components such as a semiconductor chip with a ball grid array (BGA) having many pins and a package have been increasingly mounted on a large mounting board such as a mother board (system board). Generally, these components are fixed to the mounting board using an underfill material after mounting. There sometimes occur failure or the like in a large scale integration (LSI) included in the component, in which case the component may be replaced.

However, at replacement of the component, not only the component and an underfill material are removed, but also a solder resist formed on the front surface of the mounting board may be peeled off. Further, with the peeling of the solder resist, bumps on the front surface of the mounting board may be detached therefrom. In such cases, it is difficult to use the mounting board.

Patent Document 1: Japanese Laid-open Patent Publication No. 8-32199

Patent Document 2: Japanese Laid-open Patent Publication No. 2004-186287

Patent Document 3: Japanese Laid-open Patent Publication No. 2001-7488

### SUMMARY

According to an aspect of the embodiments, a printed circuit board includes: a mounting board with a solder resist on a front surface thereof; a component mounted on the mounting board; an underfill material that fixes the component to the mounting board; and resin materials dotted between the solder resist and the underfill material.

According to another aspect of the embodiments, a manufacturing method of a printed circuit board: dotting resin materials on a solder resist on a front surface of a mounting board; mounting a component on the mounting board; and providing an underfill material that fixes the component to the mounting board in a gap between the mounting board and the component and in a gap between the resin materials and the component.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A and FIG. 1B are views illustrating a configuration of a printed circuit board according to a first embodiment;

FIG. 2A and FIG. 2B are views illustrating a state that a component 30 has been removed;

FIG. 3A to FIG. 3C are views illustrating a reference example;

FIG. 4A to FIG. 4L are sectional views illustrating a manufacturing method of the printed circuit board according to the first embodiment in the order of steps;

FIG. 5A and FIG. 5B are views illustrating examples of layout of pads 11; and

FIG. 6 is a view illustrating a configuration of a printed circuit board according to a second embodiment.

### DESCRIPTION OF EMBODIMENTS

Preferred embodiments will be explained below with reference to accompanying drawings.

### First Embodiment

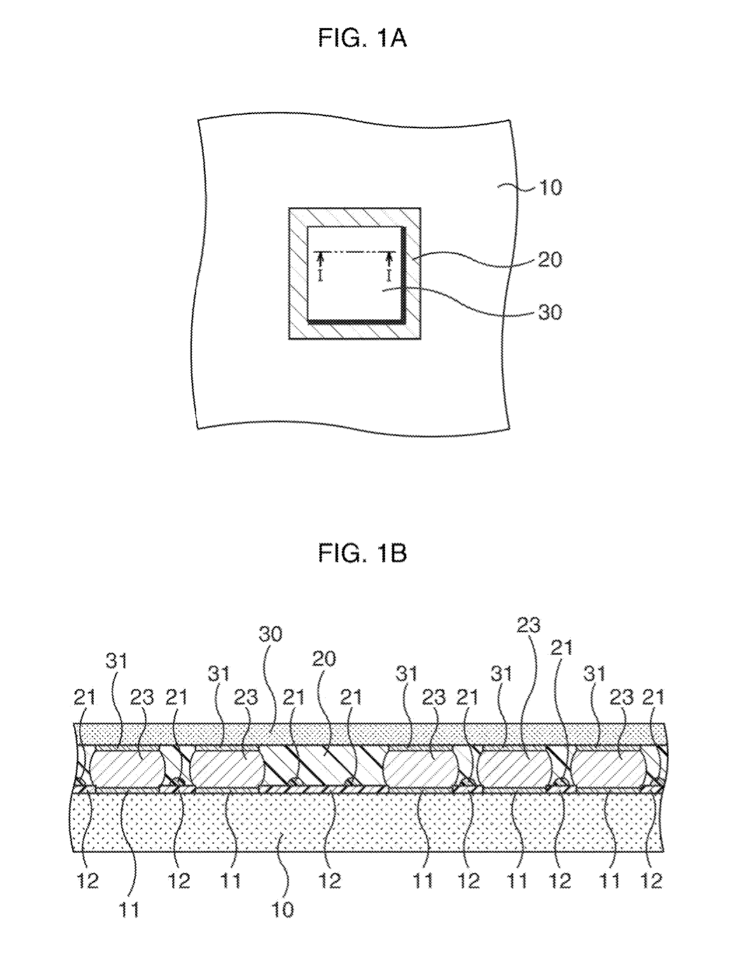

First, a first embodiment will be explained. FIG. 1A and FIG. 1B are views illustrating a configuration of a printed circuit board according to the first embodiment. FIG. 1A is a plan view and FIG. 1B is a sectional view.

In the first embodiment, as illustrated in FIG. 1A and FIG. 1B, a component 30 is mounted on a mounting board 10. The component 30 is fixed to the mounting board 10 with an underfill material 20. Pads (electrodes) 11 are arranged on a front surface of the mounting board 10, and a solder resist 12 is formed around the pads 11. In other words, most of the front surface of the mounting board 10 is covered with the solder resist 12, and the pads 11 are arranged at portions not covered with the solder resist 12. The component 30 is, for example, a BGA semiconductor chip, and pads (electrodes) 31 are arranged on a surface of the component 30 facing the mounting board 10 in a manner to face the pads 11. Further, the pads 11 and the pads 31 are connected with connection materials 23. The connection material 23 is, for example, a solder material. Furthermore, resin materials 21 are dotted on the solder resist 12. The underfill material 20 is formed to fill a gap between the mounting board 10 and the component 30. Accordingly, the underfill material 20 is located over the mounting board 10 in a manner to cover the resin materials 21, and the resin materials 21 are dotted between the solder resist 12 and the underfill material 20. Further, regions of the solder resist 12 not covered with the resin materials 21 are in contact with the underfill material 20.

A temperature at which a strength of the resin material 21 to adhere to the solder resist 12 starts to decrease when being increased in temperature may be lower than a temperature at which a strength of the underfill material 20 to adhere to the solder resist 12 starts to decrease when being increased.

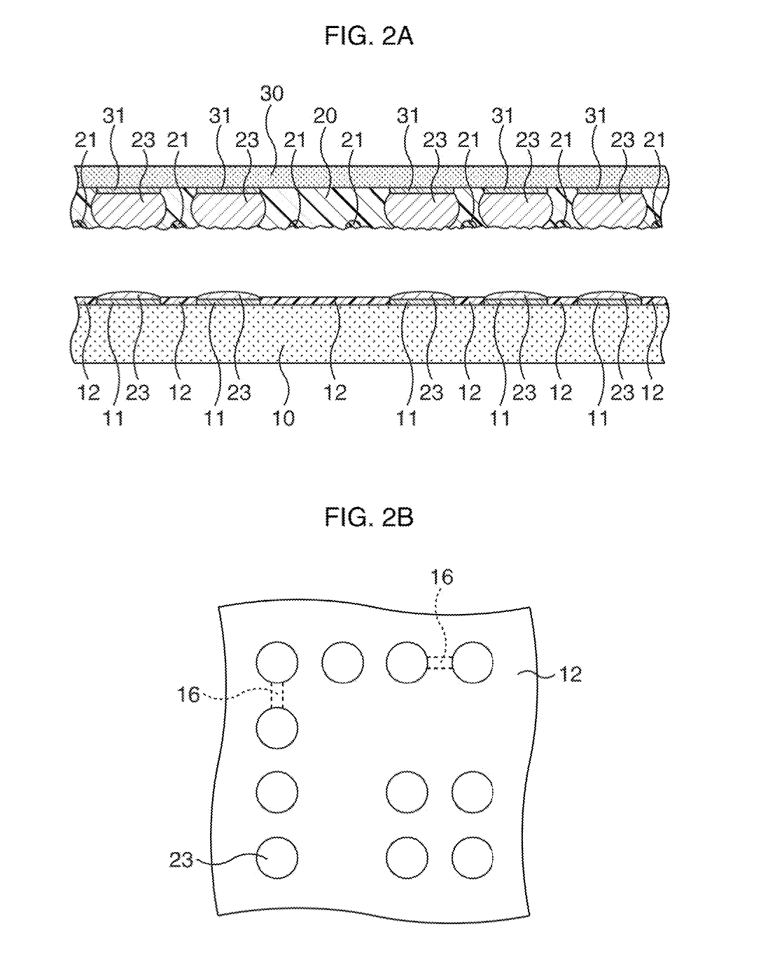

The surface mounting type printed circuit board is configured as described above. For replacing the component 30 because of failure or the like, the printed circuit board is increased in temperature. With the increase in temperature of the printed circuit board, the temperatures of the underfill material 20 and the resin materials 21 increase. Since the temperature of the resin materials 21 starting to decrease in strength to adhere to the solder resist 12 is lower than the temperature of the underfill material 20 starting to decrease in strength to adhere to the solder resist 12, the resin materials 21 become easy to peel off earlier than the underfill material 20. As the temperature increase is continued, the underfill material 20 starts to decrease in strength to adhere to the solder resist 12. At that time, since the resin materials 21 have already become easy to peel off the solder resist 12, peeling of the underfill material 20 off the solder resist 12 spreads from areas around the resin materials 21. Accordingly, as illustrated in FIG. 2A and FIG. 2B, the underfill material 20 is peeled off the mounting board 10 without peeling of the solder resist 12 off the mounting board 10. Further, since the solder resist 12 is not peeled off the mounting board 10, the pads 11 are not likely to peel off the mounting board 10. FIG. 2A is a sectional view, and FIG. 2B illustrates an upper surface of the mounting board 10 from which the component 30 has been removed. As illustrated in FIG. 2B, various wirings such as a wiring 16 connecting the pads 11 are formed under the solder resist 12 of the mounting board 10, and protection of these wirings by the solder resist 12 can be maintained because the solder resist 12 is not peeled.

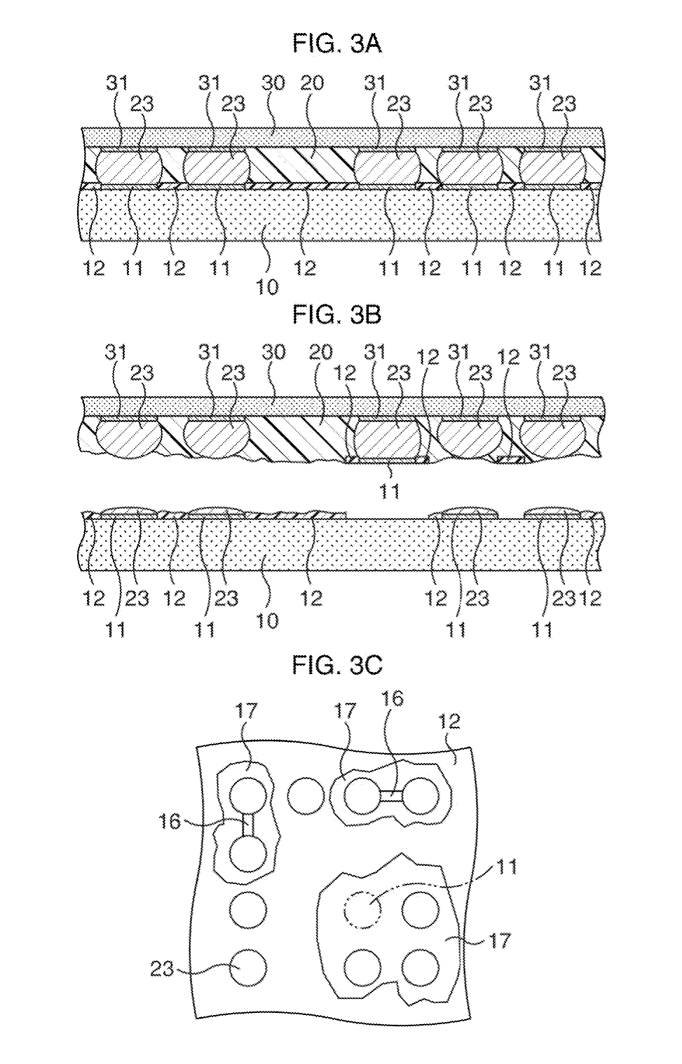

On the other hand, if the printed circuit board is increased in temperature for replacing the component 30 in a case where no resin materials 21 are provided as in a reference example illustrated in FIG. 3A, peeling of the solder resist 12 may occur as illustrated in FIG. 3B and FIG. 3C unless the strength of the underfill material 20 to adhere to the solder resist 12 is sufficiently decreased. Further, separation of the pads 11 may also occur with the peeling of the solder resist 12. In the case where the solder resist 12 has been peeled, if there are wirings such as the wiring 16 under the solder resist 12, the wirings will be exposed. The exposure of the wirings may cause short circuit after a new component for replacement is mounted.

Note that in the first embodiment, if the strength of the underfill material 20 to adhere to the solder resist 12 has been decreased to the degree as in the reference example, the resin materials 21 have become easy to peel off the solder resist 12, rarely bringing about the above problem. As described above, according to the first embodiment, it is possible to significantly suppress the peeling of the solder resist 12 when removing the component 30.

Further, in the case where the resin materials 21 are formed over the whole gap between the solder resist 12 and the underfill material 20, the fixation of the component 30 by the underfill material 20 may be insufficient. In contrast, in the first embodiment, the underfill material 20 is in contact with the regions of the solder resist 12 not covered with the resin materials 21, so that the component 30 is sufficiently fixed to the mounting board 10 by the underfill material 20.

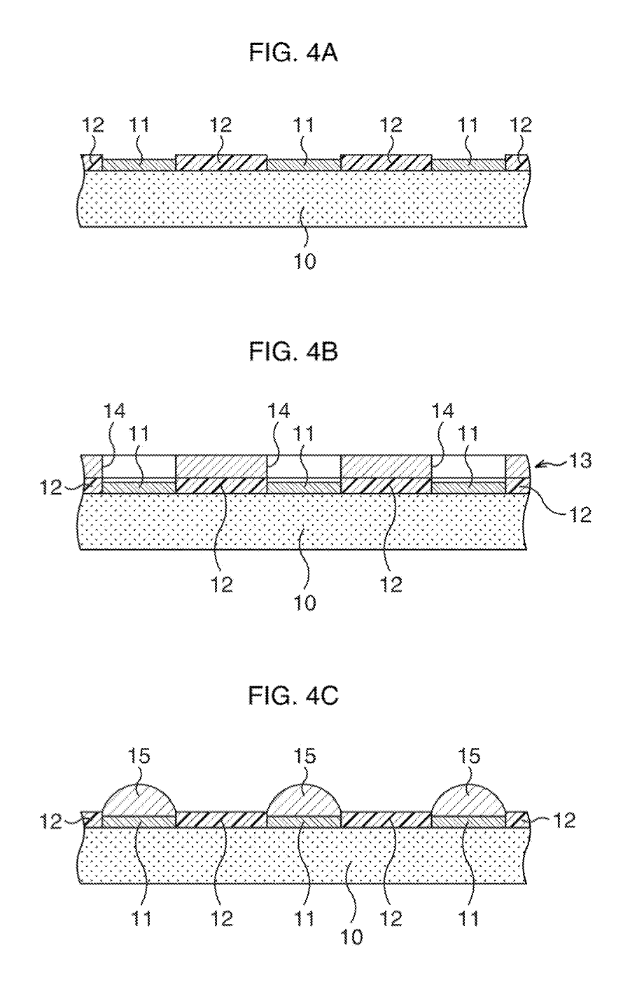

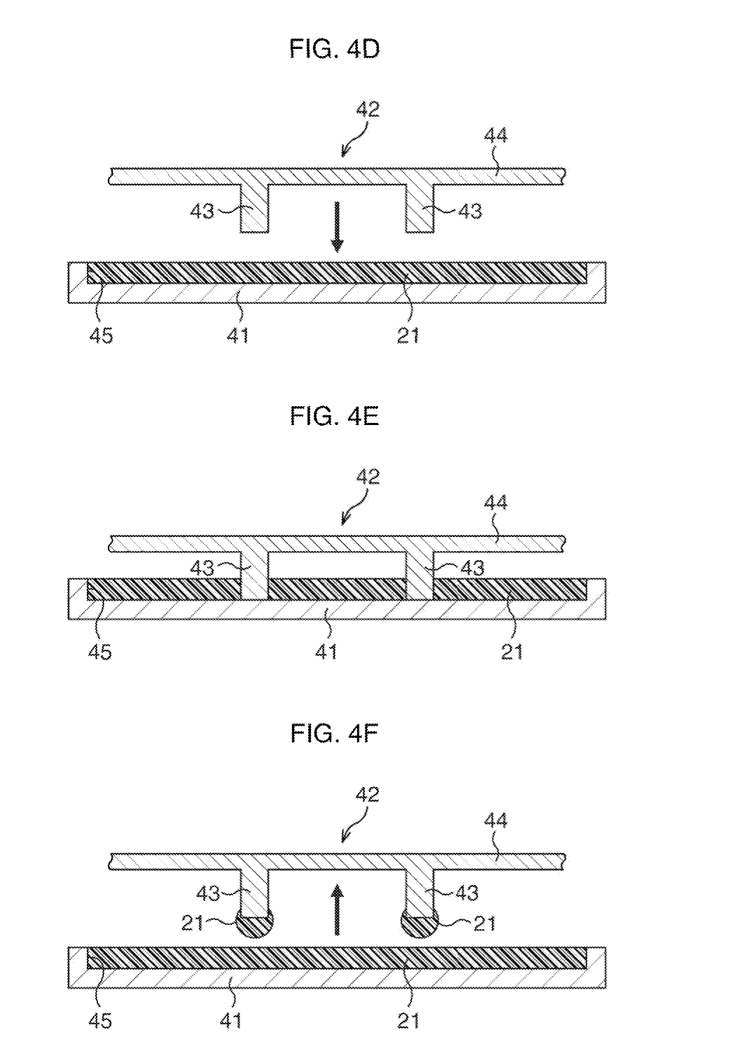

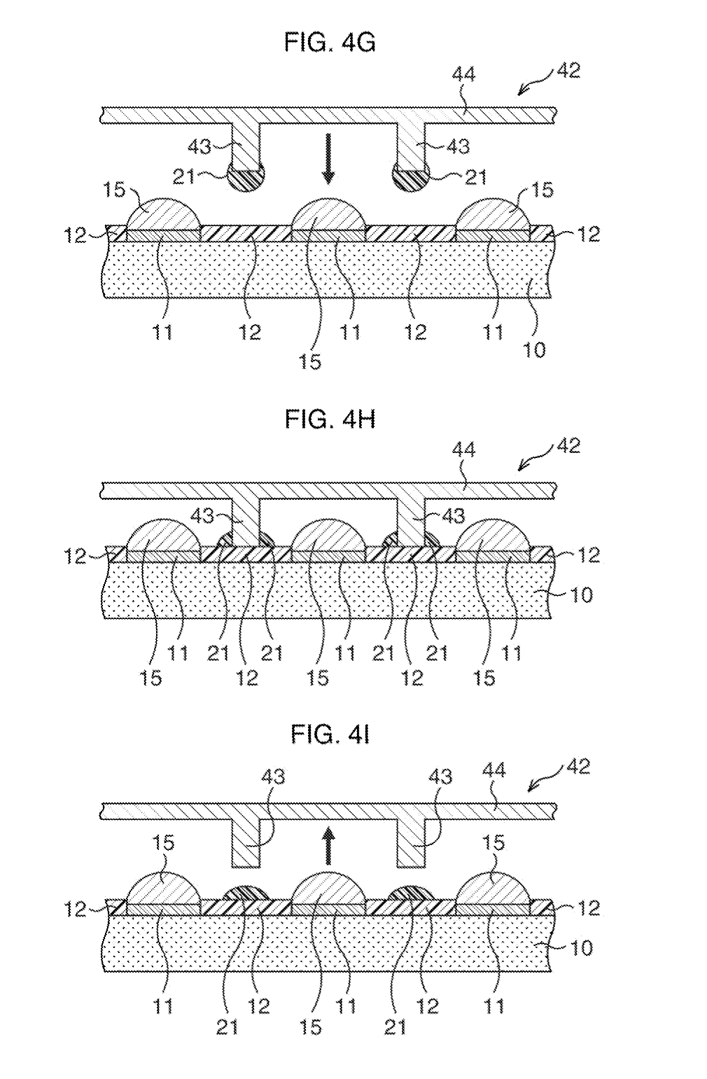

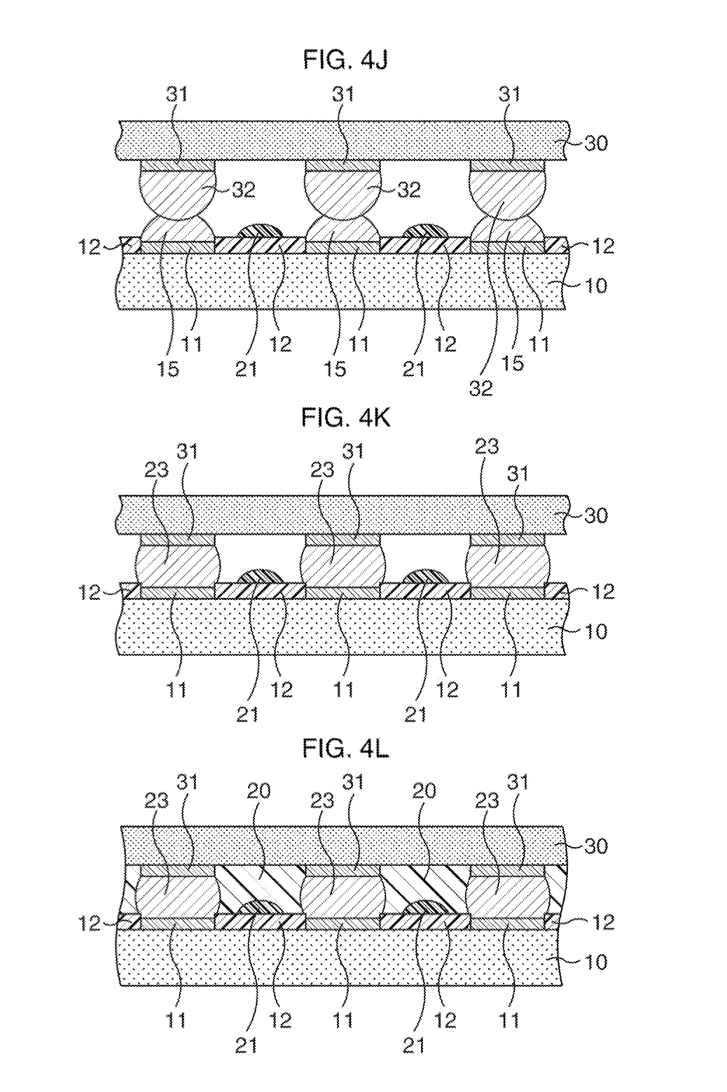

Next, a manufacturing method of the printed circuit board according to the first embodiment will be explained. FIG. 4A to FIG. 4L are sectional views illustrating the manufacturing method of the printed circuit board according to the first embodiment in the order of steps.

First, as illustrated in FIG. 4A, the solder resist 12 is formed on the front surface of the mounting board 10 on which the wirings and the pads 11 are formed. In this event, the upper surface of the solder resist 12 is located to be higher than the upper surfaces of the pads 11. The different between them may be, for example, about 20 μm. Then, as illustrated in FIG. 4B, a mask 13 having openings 14 matching the pads 11 is provided over the solder resist 12. A metal mask may be used as the mask 13, for example. The thickness of the mask 13 may be determined according to the amount of a solder paste to be applied on the pads 11. Thereafter, as illustrated in FIG. 4C, solder pastes 15 are provided on the pads 11 by a printing method using the mask 13. Then, the mask 13 is removed.

Further, as illustrated in FIG. 4D, a liquid for the resin materials 21 is prepared in a container 41 provided with a housing unit 45 having a predetermined depth. A jig 42 in which pins 43 are supported by a pin support unit 44 is prepared. The pins 43 are arranged in the same pattern as that of the resin materials 21 to be arranged on the solder resist 12. The jig 42 may be made of, for example, stainless steel. Then, as illustrated in FIG. 4E, the pins 43 are immersed in the liquid for resin materials 21, and the tips of the pins 43 are brought into contact with the bottom surface of the housing unit 45. Thereafter, as illustrated in FIG. 4F, the jig 42 is pulled up. An almost fixed amount of the resin material 21 adheres to the tip of each pin 43.

Then, as illustrated in FIG. 4G, the jig 42 in which the resin materials 21 adhere to the tips of the pins 43 is moved to above the mounting board 10. As illustrated in FIG. 4H, the jig 42 is lowered to bring the resin materials 21 into contact with the solder resist 12. At this time, the tips of the pins 43 may be brought into contact with the solder resist 12. Thereafter, as illustrated in FIG. 4I, the jig 42 is pulled up. As a result, the resin materials 21 adhering to the tips of the pins 43 remain on the solder resist 12. In other words, the resin materials 21 are transferred to the top of the solder resist 12. Since the amount of the resin material 21 adhering to the tip of each pin 43 is almost constant, the amount of the resin material remaining on each location on the solder resist 12 is almost constant, too. For example, the resin materials 21 may be arranged away from the solder pastes 15, and the positions of top portions of the resin materials 21 may be located closer to the mounting board 10 than are the positions of top portions of the solder pastes 15. If the resin materials 21 are not away from the solder pastes 15 but in contact with the solder pastes 15, it may be failed to obtain excellent connection materials 23 thereafter. Further, the contact area of the underfill material 20 and the solder resist 12 may not be sufficient. If the positions of the top portions of the resin materials 21 are away farther from the mounting board 10 than are the positions of the top portion of the solder pastes 15, that is, if the resin materials 21 are too high, the resin materials 21 highly possibly flow to adhere to the solder pastes 15. Also in this case, it may be failed to obtain excellent connection materials 23 thereafter so that the contact area of the underfill material 20 and the solder resist 12 is not sufficient.

Subsequently, as illustrated in FIG. 4J, the component 30 having solder balls 32 provided on the pads 31 is mounted on the mounting board 10 such that the solder balls 32 come into contact with the solder pastes 15. Then, the solder pastes 15 and the solder balls 32 are molten by heating, and then the molten solder pastes 15 and solder balls 32 are solidified by subsequent cooing. As a result, as illustrated in FIG. 4K, the connection material 23 are made from the solder paste 15 and the solder ball 32, and the component 30 is mounted on the mounting board 10. The heating temperature and time may be determined in consideration of the melting points and so on of the solder pastes 15 and the solder balls 32. For example, they may be kept at a temperature of 150° C. or higher for about 3 to 4 minutes. Further, as a result of heating, the resin materials 21 may be brought into a semi-cured state or a full-cured state according to the material thereof. Subsequently, as illustrated in FIG. 4L, the underfill material 20 is made to flow into the gap between the component 30 and the mounting board 10, and cured by heating. The heating temperature and time may be determined in consideration of the curing temperature of the underfill material 20, the melting point of the connection materials 23 and so on. For example, they may be kept at a temperature of 125° C. to 150° C. for about 15 to 20 minutes. The flow of the underfill material 20 may be performed, for example, by application of the material of the underfill material 20.

The printed circuit board according to the first embodiment can be thus manufactured.

Incidentally, the depth of the housing unit 45 of the container 41 is not particularly limited, and is preferably determined according to the amount of the resin material 21 made to adhere to the top of the solder resist 12. For example, the amount is set to about twice the height of the resin material 21 made to adhere to the top of the solder resist 12 though depending on the viscosity of the resin material 21.

The type of the underfill material 20 and the type of the resin materials 21 are not particularly limited. For example, in a case where an epoxy-based resin is for the underfill material 20, it is preferable to use an epoxy-based resin or an acryl-based resin lower in softening point (softening temperature) than the underfill material 20 for the resin materials 21.

Further, the length and the thickness of the pins 43 may differ according to the position on the underfill material 20 to which the resin material 21 is made to adhere and the distances from the solder pastes 15 around the position and so on. For example, the resin materials 21 provided in a region where the solder pastes 15 are sparsely arranged may be relatively large, and the pins 43 may be thick according to the size of the resin materials 21. Conversely, the resin materials 21 provided in a region where the solder pastes 15 are densely arranged are preferably relatively small, and the pins 43 may be thin according to the size of the resin materials 21.

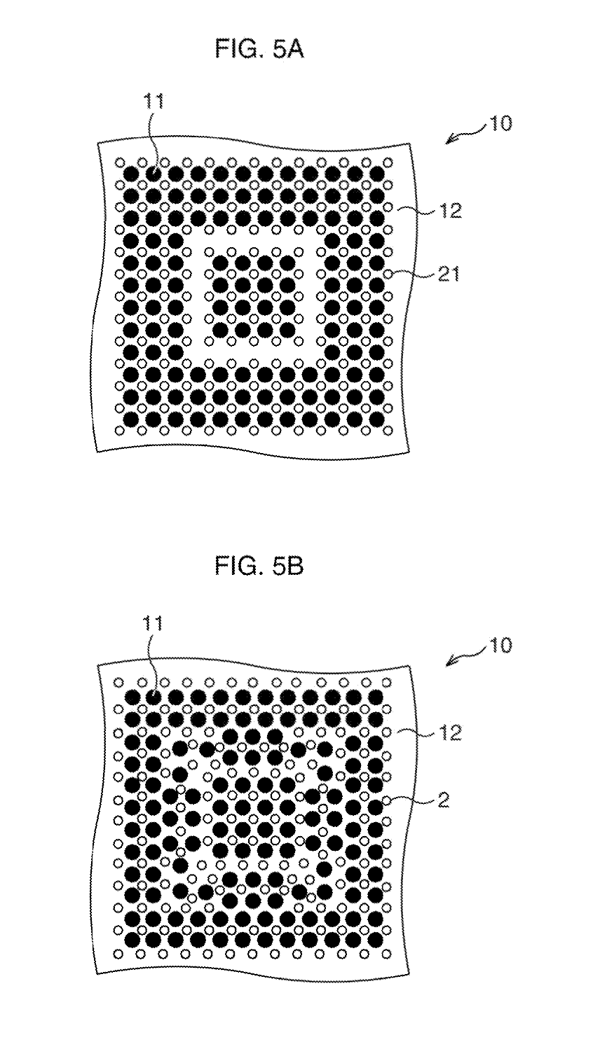

The layout of the pads 11 is not particularly limited, and the pads 11 may be arranged in a relatively regularly arranged as illustrated in FIG. 5A, or may be relatively irregularly arranged as illustrated in FIG. 5B. For forming the resin materials 21, it is possible to easily arrange the resin materials 21 at desired positions, if the jig 42 is used in which the pins 43 are laid out according to the layout of the pads 11. Incidentally, formation of the resin materials 21 is not limited to the transfer using the above-described jig, and may be performed also by a screen printing method or an ink-jet printing method. However, the transfer using the jig is preferable in terms of accuracy, cost and so on.

### Second Embodiment

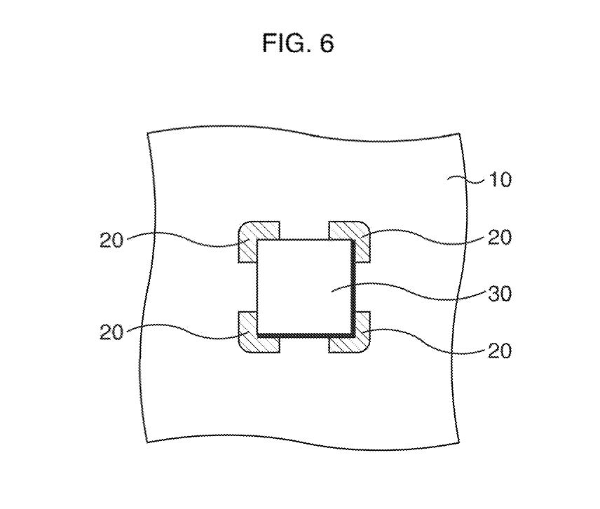

Next, a second embodiment will be explained. FIG. 6 is a view illustrating a configuration of a printed circuit board according to the second embodiment.

In contrast to the first embodiment, in which the underfill material 20 is provided in the whole gap between the component 30 and the mounting board 10, the underfill material 20 is provided only near four corners of the component 30 having a rectangular plane shape in the second embodiment. The other configuration is similar to that of the first embodiment. For example, the first embodiment may be called a full immersion coating method, and the second embodiment may be called a corner bonding method.

As described above, the second embodiment has the configuration similar to that of the first embodiment except that the position where the underfill material 20 is provided is different. Also in the second embodiment, it is possible to suppress the peeling of the solder resist 12 when the component 30 is removed as in the first embodiment.

Incidentally, it is preferable both in the first embodiment and the second embodiment that the total area of surfaces of the resin materials 21 in contact with the solder resist 12 is 20% to 80% of the area of the surface of the solder resist 12 covered with the underfill material 20. When the area ratio is less than 20%, the effect of improving the peeling property obtained by providing the resin materials 21 may be insufficient. When it exceeds 80%, the contact area of the solder resist 12 and the underfill 20 may be small to make it hard to ensure sufficient adhesive strength. Further, the area ratio is preferably 50% or more and it is also preferably 70% or less.

According to the above printed circuit board and so on, appropriate resin materials are provided on a solder resist, thereby making it easy to peel an underfill material when removing a component and making it possible to suppress peeling of the solder resist.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A printed circuit board, comprising:
a mounting board with a solder resist on a front surface thereof;
a component mounted on the mounting board;
an underfill material that fixes the component to the mounting board; and
resin materials dotted between the solder resist and the underfill material.

2. The printed circuit board according to claim 1, wherein a softening point of the resin material is lower than a softening point of the underfill material.

3. The printed circuit board according to claim 1, wherein a softening point of the resin material is higher than an operation temperature of the component.

4. The printed circuit board according to claim 1, wherein a total area of surfaces of the resin materials in contact with the solder resist is 20% to 80% of an area of a surface of the solder resist covered with the underfill material.

5. A manufacturing method of a printed circuit board, comprising:
dotting resin materials on a solder resist on a front surface of a mounting board;
mounting a component on the mounting board; and
providing an underfill material that fixes the component to the mounting board in a gap between the mounting board and the component and in a gap between the resin materials and the component.

6. The manufacturing method of a printed circuit board according to claim 5, wherein a softening point of the resin material is lower than a softening point of the underfill material.

7. The manufacturing method of a printed circuit board according to claim 5, wherein a softening point of the resin material is higher than an operation temperature of the component.

8. The manufacturing method of a printed circuit board according to claim 5, wherein a total area of surfaces of the plurality of resin materials in contact with the solder resist is 20% to 80% of an area of a surface of the solder resist covered with the underfill material.

9. The manufacturing method of a printed circuit board according to claim 5, wherein the dotting a plurality of resin materials comprises:
making resin materials to adhere to tips of pins provided at a jig;
bringing the resin materials into contact with the solder resist; and
pulling up the jig to leave the resin materials on the solder resist.

10. The manufacturing method of a printed circuit board according to claim 5, wherein in the dotting resin materials, positions of top portions of the resin materials are located closer to the mounting board than are a position of a top portion of a solder paste on an electrode of the mounting board.

11. The manufacturing method of a printed circuit board according to claim 5, wherein in the dotting resin materials, the resin materials are arranged away from a solder paste on an electrode of the mounting board.
